(19) United States
(12) Patent Application Publication
(10) Pub. No.: US 2026/0300566 A1
(43) Pub. Date: Oct. 1, 2026

(54) ENHANCED COMPUTATION OF ROBUST LOSS FUNCTIONS USING ADAPTIVE ANNEALING FACTORS

(71) Applicant: Mitsubishi Electric Research Laboratories, Inc., Cambridge, MA (US)

(72) Inventors: Pedro Miraldo, Cambridge, MA (US); Valter Piedade, Lisbon (PT)

(73) Assignee: Mitsubishi Electric Research Laboratories, Inc., Cambridge, MA (US)

(21) Appl. No.: 19/089,346

(22) Filed: Mar. 25, 2025

(51) Int. Cl. G06F 30/13

(52) U.S. Cl. CPC G06F 30/13

(57) ABSTRACT

In an embodiment, a computer-vision method for performing a task in an environment includes collecting data representing the environment and collecting a structure of a model of the environment suitable for performing the task. The method continues with determining values of the structure of the model fitting the collected outlier-contaminated environmental data by solving an M-estimation optimization problem that iteratively minimizes a robust loss function of a solution for fitting the model into the data using a parameter defining a convex space of the solution until a termination condition is met. For at least one current iteration, a current parameter is selected from multiple semi-random parameters representing a previous parameter determined during a previous iteration and modified with annealing factors randomly sampled within a predetermined range. The task may then be performed using the model of the environment when the termination condition is met.

### TECHNICAL FIELD

Aspects of the disclosure are related to the field of computer vision, and specifically, to systems, methods, and software for computing robust loss functions.

### BACKGROUND

In many practical applications, such as autonomous navigation, robot localization, and 3D reconstruction, performing a task in a physical environment requires constructing an accurate model of that environment. For instance, an autonomous vehicle must create a model of its surroundings to navigate safely, while a robotic arm requires a precise model of its workspace to execute tasks effectively. These models are critical as they provide structured representations of the environment, facilitating downstream processes such as decision-making, control, and further analysis. However, constructing such models is particularly challenging due to the noisy nature of real-world measurements, which often results in outlier-contaminated data that can significantly impair the accuracy and reliability of the models.

Further complicating the problem is that the required model often depends heavily on the specific task, even within the same application. In 3D reconstruction, for example, a model for mapping a building's layout will differ in complexity and focus from a model used to identify objects in a cluttered environment. Similarly, within a single application like autonomous driving, different subtasks may demand vastly different models of the environment. For example, the system may need to generate a linear model of road markings through simple regression of image data in one instance, and in the next, construct a highly nonlinear model to represent surrounding traffic dynamics. This task-specific dependency makes it challenging to rely on generic modeling approaches that use domain-specific assumptions or preprocessed data.

This variability also imposes significant computational demands, as robust and accurate modeling often requires sophisticated algorithms. However, many real-world systems, particularly those embedded in low-power devices, are constrained by limited computational resources. The need to balance robustness against noisy, outlier-contaminated data with computational efficiency presents a significant challenge in designing practical solutions for these applications.

### SUMMARY

Technology is disclosed herein that improves the field of computer vision by way of systems, methods, and software for enhanced parameter optimization. The enhanced parameter optimization disclosed herein provides a computationally efficient way to compute model parameters while remaining robust in the face of imperfect data.

In an embodiment, a computer-vision method for performing a task in an environment represented by noisy measurements is implemented using a processor coupled with stored instructions implementing the method. The instructions, when executed by the processor, carry out steps of the method, including collecting data representing the environment and collecting a structure of a model of the environment suitable for performing the task. In some embodiments, the data may be contaminated with outliers caused at least in part by the noisy measurements of the environment.

The method continues with determining values of the structure of the model fitting the collected outlier-contaminated environmental data by solving an M-estimation optimization problem that iteratively minimizes a robust loss function of a solution for fitting the model into the data using a parameter defining a convex space of the solution until a termination condition is met. For at least one current iteration, a current parameter is selected from multiple semi-random parameters representing a previous parameter determined during a previous iteration and modified with annealing factors randomly sampled within a predetermined range. The task may then be performed using the model of the environment when the termination condition is met.

In the same or alternative embodiments, the current parameter may be a shape parameter of the robust loss function, and the multiple semi-random parameters, from which the current parameter is selected, may be different instances of the shape parameter, each modified using a corresponding one of the annealing factors. Thus, for at least the one current iteration, each instance of the shape parameter may be computed based on a previous instance of the shape parameter and a corresponding one of the annealing factors.

This Overview is provided to introduce a selection of concepts in a simplified form that are further described below in the Technical Disclosure. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure may be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views. While several embodiments are described in connection with these drawings, the disclosure is not limited to the embodiments disclosed herein. On the contrary, the intent is to cover all alternatives, modifications, and equivalents.

FIG. 1 illustrates an operational environment with enhanced parameter optimization in an embodiment.

FIG. 2 illustrates a parameter optimization process in an embodiment, which may be employed in the context of the operational environment of FIG. 1.

FIG. 3 illustrates a software architecture for implementing a parameter optimization process in an embodiment.

FIG. 4 illustrates another parameter optimization process in an embodiment, which may be implanted by the software architecture illustrated in FIG. 3.

FIG. 5 illustrates an operational sequence associated with an implementation of the parameter optimization process of FIG. 4 with respect to the software architecture of FIG. 3 in an embodiment.

FIGS. 6A-6G illustrate an operational scenario associated with an implementation of the parameter optimization process of FIG. 4 with respect to the software architecture of FIG. 3 in an embodiment.

FIG. 7 illustrates a computing system suitable for implementing the various operational environments, architectures, processes, scenarios, and sequences discussed below with respect to the other Figures.

### DETAILED DESCRIPTION

A unified approach to the problems and challenges discussed above enables modeling an environment from noisy measurements containing outlier-contaminated data while tailoring the model to a specific task at hand. By integrating adaptive and robust algorithms, various embodiments disclosed herein aim to overcome the limitations of traditional methods that struggle with issues such as non-convex optimization, fixed parameter tuning, and high computational complexity.

More specifically with respect to the problems and challenges, to determine a model that fits or represents environmental data contaminated with outliers, it is essential to establish a structure for the model based on the specific task at hand. For example, when modeling traffic lanes, a structure might include a linear model of a line passing through the environment, whereas for point cloud registration, the structure might involve a translation and rotation matrix. Defining this model structure simplifies the process by constraining the problem to a domain-specific representation, making it less computationally intensive compared to solving the full problem without predefined structure. This step ensures the model is tailored to the task requirements while minimizing unnecessary computational complexity.

Next, there is a need to estimate parameters of the structure of the model such as point and angle of the line and/or values of the translation and the rotation. This involves solving a minimization problem by adjusting the parameters or values of the structure of model to best align with the data. However, this is a computationally challenging task due to the presence of outliers and the inherent complexity of the problem. Outliers can significantly distort results, and the high dimensionality of the solution space exacerbates the difficulty, making traditional iterative optimization methods prone to being trapped in local minima.

Least squares estimation, a standard approach for such optimization, is particularly sensitive to outliers because it minimizes squared residuals, amplifying the impact of extreme values. Addressing this requires robust loss functions and iterative search strategies. However, such iterative approaches demand significant computational resources, particularly in high-dimensional spaces. The non-convex nature of the problem further complicates convergence, necessitating methods that can avoid local minima and provide globally robust solutions.

An alternative potential strategy would be to sample the solution space randomly and evaluate each sampled solution against specific criteria. This approach would simplify the computation and allows parallel execution, enhancing the system's performance. However, the practicality of this method is limited by the unbounded and high-dimensional nature of the solution space, which makes comprehensive sampling computationally infeasible. Nevertheless, it is an object of some embodiments to extend this understanding to arrive at the practical and computationally efficient solution.

To that end, some embodiments disclosed herein leverage the insight that model fitting using least squares estimation can be transformed through M-estimation. M-estimation is a statistical estimation method that minimizes the difference between a model and data using a robust loss function. Unlike traditional least squares, which uses the squared residuals, M-estimation allows for a variety of loss functions that are less sensitive to outliers, such as Huber loss or Tukey's bisquare loss. By applying these robust loss functions, M-estimation reduces the influence of extreme values, making it a powerful tool for robust regression and parameter estimation in the presence of noise or non-normal errors.

Mathematically, M-estimation minimizes the sum of a loss function ρ(r_i) applied to residuals r_i=y_i−f(x_i;θ), where f(x_i;θ) is the model prediction, and θ represents the parameters to estimate. The choice of ρ determines the robustness of the method, with common choices balancing the treatment of small and large residuals. This flexibility allows M-estimation to perform well in a wide range of applications, including cases with heavy-tailed distributions or outlier-contaminated data.

Some embodiments are based on understanding that choice of ρ can be made robust to mitigate the influence of outliers in the estimation process by making the loss function dependent on a parameter σ (sometimes referred to as the shape parameter) defining a convex solution space. Example of such a robust loss function is the Geman-McClure loss. By focusing on sampling this parameter σ rather than the high-dimensional solution space, the problem can be reduced to a lower-dimensional search—potentially as simple as one-dimensional sampling. This shift dramatically simplifies the computational effort required.

Even so, the shape parameter itself may be unbounded, and constraining it could introduce undesirable dependencies on domain knowledge. Additionally, evaluating the effectiveness of the sampled parameter and iteratively refining the sampling space remains challenging, particularly when adapting to specific tasks.

To address these issues, certain embodiments introduce a hyperparameter, referred to as the annealing factor, which governs the robust loss function's shape parameter. The annealing factor can be sampled within a predefined range that is independent of any specific task or domain. By iteratively modifying the parameter based on the best results from previous iterations, the sampling range adapts naturally. This semi-random, probabilistic sampling approach enables the system to refine the parameter iteratively while remaining computationally efficient and robust across different domains and tasks.

In effect, the disclosed technology offers a scalable and adaptable framework for modeling outlier-contaminated environmental data. By combining robust M-estimation, parameter sampling, and annealing-based iterative refinement, these embodiments provide a powerful solution to a long-standing computational challenge in model fitting and task-specific optimization, with applications in autonomous navigation, robotic localization, 3D reconstruction, and other environments requiring task-specific modeling of noisy, outlier-contaminated data. It specifically addresses task-dependent models fitting into environmentally noisy measurements contaminated by outliers under computational constraints in a task and domain agnostic manner, enabling scalable and adaptable solutions for real-world systems.

Various practical applications of the technology disclosed herein may be appreciated from the discussion above, including—but not limited to—the following applications.

Autonomous Navigation: In self-driving cars, this technology can be used to model the environment by accurately identifying and fitting geometric structures, such as road boundaries, lane markings, and obstacles, even in the presence of sensor noise or outlier data. The robust modeling ensures safe navigation in complex scenarios, such as adverse weather or cluttered urban environments.

Robotic Localization and Mapping: Robots performing Simultaneous Localization and Mapping (SLAM) can benefit from this approach by improving pose estimation and map accuracy. The adaptive annealing strategy enables efficient handling of data contaminated by outliers, such as incorrect feature matches or sensor anomalies, leading to better path planning and decision-making in real-time.

3D Reconstruction: The technology can enhance 3D reconstruction tasks in augmented reality (AR) or virtual reality (VR) applications by fitting models to point cloud data from 3D scanners. It ensures accurate reconstruction of objects or scenes, even with incomplete or noisy input data.

Medical Imaging: In medical diagnostics, the framework can be applied to reconstruct and align images from noisy datasets, such as CT or MRI scans. The robust loss functions mitigate the impact of artifacts or missing data, enabling precise modeling for better diagnostic outcomes.

Industrial Automation: Automated systems in manufacturing can use this method for object recognition and manipulation. By modeling the workspace and identifying task-specific geometries, the technology improves the accuracy and reliability of robotic arms handling components under variable conditions.

Aerial Mapping and Surveying: Drones equipped with cameras and LIDAR sensors can use this approach for mapping and terrain modeling. The robust optimization ensures accurate data fusion and modeling even in areas with sparse or noisy measurements, enabling applications like agriculture monitoring or infrastructure inspection.

Security and Surveillance: In surveillance systems, this technology can help in identifying and tracking objects or individuals in noisy visual data from cameras. The task-specific optimization enhances reliability in diverse environments, such as crowded public spaces.

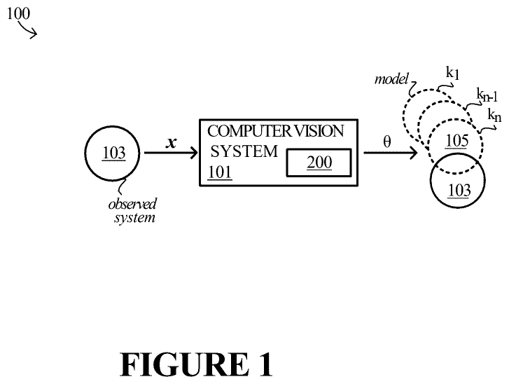

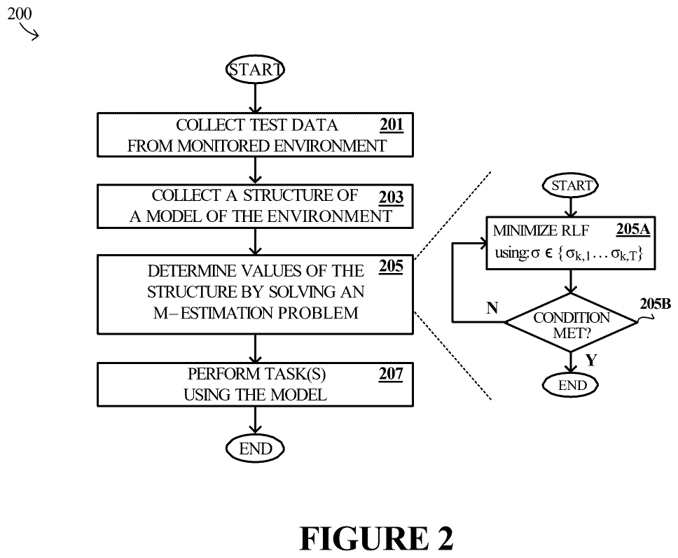

Turning now to the figures, FIG. 1 illustrates an operational environment 100 in an implementation. Operational environment 100 includes computer vision system 101, observed environment 103, and model 105. Computer vision system 101, which may be implemented in computing hardware, software, and/or firmware executes a parameter optimization process 200, illustrated in in FIG. 2, to optimize parameters of model 105 based on input data associated with observed environment 103. Parameter optimization process 200 ensures that model 105 accurately reflects observed environment 103, enhancing the predictive and analytical capabilities of model 105.

For example, in the context of 3D point cloud registration, the input data may be 3D point clouds representing observed environment 103. These point clouds are sets of 3D coordinates that capture the spatial arrangement of points in the environment. The input data can be obtained through various methods such as LiDAR (Light Detection and Ranging), stereo cameras, structured light scanners, depth cameras, and photogrammetry. These techniques provide raw 3D point cloud data, which is then processed and used in the 3D point cloud registration method to align and merge multiple point clouds, resulting in a coherent representation of the observed environment. The parameter optimization algorithm seeks to optimize the parameters of the model that aligns these point clouds accurately, accounting for potential noise and outliers in the data.

Other example applications of the enhanced parameter optimization techniques disclosed herein include Simultaneous Localization and Mapping (SLAM) systems, which use sensor data from LiDAR, cameras, and inertial measurement units (IMUs) for accurate navigation. Robust control systems benefit from parameter optimization to ensure stability and performance in dynamic environments, using measurements from sensors monitoring system variables. In computer vision and image processing, these techniques improve tasks like image segmentation and object recognition, leveraging images and videos captured by cameras. Machine learning applications rely on parameter optimization for training models and finding optimal hyperparameters, using diverse datasets like text, images, and numerical data. Structural health monitoring employs parameter optimization to detect anomalies and predict failures, utilizing sensor data from accelerometers and strain gauges. Financial modeling uses parameter optimization to predict market trends and manage risks, drawing from historical financial data and economic indicators. As such, the enhanced parameter optimization techniques are not limited to the 3D point cloud registration examples provided herein but rather apply as well to numerous and diverse applications and environments.

As mentioned, computer vision system 101 may be implemented in hardware, software, firmware, or any combination thereof, providing flexibility in its deployment to suit different operational requirements. Additionally, computer vision system 101 can be implemented in a stand-alone manner or integrated within the context of other systems or sub-systems in operational environment 100, offering further adaptability and seamless integration with existing infrastructures.

A hardware-based version of computer vision system 101 may be directly implemented in specialized chips or embedded systems to ensure real-time processing and low latency. A software-based version of computer vision system 101 may be deployed as an application running on general-purpose computers or servers, offering flexibility and ease of updates. A firmware-based version of computer vision system 101 may involve embedding the system in the firmware of devices, such as IoT devices or industrial controllers, balancing performance and flexibility. A hybrid approach may also be employed, combining hardware, software, and firmware components to leverage the strengths of each. Alternatively, or in addition, a cloud-based version of computer vision system 101 may be deployed in cloud environments, allowing for scalable and flexible deployment, as well as access to advanced machine learning and data analytics tools. In edge computing scenarios, computer vision system 101 may be deployed closer to the data source to reduce latency and bandwidth usage.

Computer vision system 101 employs parameter optimization process 200—illustrated in FIG. 2—to optimize parameters of model 105 in view of data collected with respect to observed environment 103. Parameter optimization process 200 may be implemented in program instructions in the context of software, and/or firmware elements of computer vision system 101, or in specialized circuitry configured to execute the logic of parameter optimization process 200. The logic (whether embodied in program instructions or specialized circuitry), when executed by one or more processing devices of one or more suitable computing devices, directs the one or more computing devices to operate as follows, referring to the steps of FIG. 2, and to a system in the singular for purposes of clarity.

In operation, the system collects test data from a monitored environment (Step 201). The data may be obtained through various techniques, depending on the nature of the observed system and model. For example, direct measurement techniques may be employed to gather data in real-time from sensors and instruments associated with the observed system, either through automated monitoring systems or manual collection by human operators. Data logging may also be employed to capture and store data from events and operations in systematic logs or experimental records. Simulated data generation using computational models can create synthetic data that mimics real-world conditions, while data aggregation consolidates information from multiple sources into a comprehensive dataset through techniques like data mining and database integration. Remote sensing may be employed to acquire data from a distance using specialized sensors and instruments, such as satellite imaging and aerial photography.

Furthermore, the observed data may come from various sources depending on the nature of observed system and model. For instance, sensors may measure physical quantities, such as temperature, pressure, motion, or light. Examples include environmental sensors that measure temperature, humidity, and air quality; positioning sensors such as GPS, gyroscopes, and accelerometers; imaging sensors such as cameras, LiDAR, and RADAR; logs and records and other such data recorded over time, including system logs and historical records; simulation data generated through computational models that simulate real-world phenomena such as weather models, mechanical models, and the like. The observed data may even be provided via user input and crowdsourced information such as surveys and questionnaires, mapping applications, and other such data collected from individuals.

Next, the system collects a structure of a model of the environment suitable for performing the task (Step 203). The model structure may be defined based on task-specific requirements, including, but not limited to, geometric transformations, feature alignments, or spatial constraints. It may be appreciate that, as different tasks are received, a structure of the model specific to the task may be derived for each task, but the same framework is used to determine the parameters for fitting the derived model structures, making the method applicable across multiple domains and tasks.

For example, information may be gathered about the environment that is organized in a way that allows the model to effectively perform the intended task. The structure may include geometric and spatial information that represents the observed environment. In the context of 3D point cloud registration, the structure may be a 3D model or a point cloud that captures the positions and shapes of objects within the environment. In pose estimation, the structure may be the spatial arrangement of key points on an object or a human body, captured by sensors or cameras. In image segmentation, the structure may be the segmented regions within an image, representing different objects or areas. In motion capture, the structure may be the tracked positions and orientations of markers or joints over time. In scene reconstruction, the structure may be a 3D model of an entire scene, including the geometry and spatial relationships of objects. In facial recognition, the structure may be the arrangement of facial features and landmarks, captured by cameras. In robotics navigation, the structure may be a map of the environment, including obstacles and navigable paths.

The system continues at Step 205 with determining values of the structure of the model fitting the collected outlier-contaminated environmental data. This step is accomplished by the system solving an M-estimation optimization problem that, at Step 205A, iteratively minimizes a robust loss function of a solution for fitting the model into the data using a parameter defining a convex space of the solution until, at Step 205B, a termination condition is met. In some embodiments, the robust loss function may be a Geman-McClure function, for example, that reduces the influence of extreme outliers by dynamically adjusting the weight of residuals based on a shape parameter. Thus, the shape parameter of the Geman-McClure function may be iteratively updated using a sampling strategy within an adaptive annealing framework applied in Steps 205A-205B.

For at least one iteration of Step 205A, a current parameter (σ_k) is selected from multiple semi-random parameters (σ_k,1 . . . σ_k,T) representing a previous parameter (σ_k−1) determined during a previous iteration and modified with annealing factors (γ_k,1 . . . γ_k,T) randomly sampled within a predetermined range. Thus, at a current iteration k, the multiplication of each annealing factor in the set with the previous parameter results in the set of semi-random parameters from which the current parameter is selected.

The task may then be performed using the model of the environment when the termination condition is met (Step 207). Examples of the task include 3D point cloud registration, pose estimation, image segmentation, motion tracking, scene reconstruction, facial recognition, robotic navigation, object detection, and the like. In some embodiments, the termination condition may be determined based on the convergence of model parameters, scoring consistency, and/or depletion of promising hypotheses in a priority queue (discussed in more detail below).

In some embodiments, the system collects a previous solution and the previous parameter of a convex space of the previous solution during the previous iteration. The system may then sample the annealing factors on the predetermined or predefined range using a probabilistic sampling method to optimize the convexity of the solution space. The system then modifies the previous parameter with the sampled values of the annealing factors to produce the multiple semi-random parameters. Each computational combination of the previous parameter with a different one of the annealing factors may be considered a hypothesis, resulting in a set of possible hypotheses from which promising ones are selected for further exploration during a subsequent iteration. The system may consider, evaluate, or otherwise compute the hypotheses in parallel with each other during each iteration to enhance computational efficiency.

During each iteration, the system compares each of the multiple semi-random parameters with the previous solution to select a value of the current parameter. Alternatively, or in addition, the comparison and selection may be accomplished using a scoring function that evaluates the robustness of candidate parameters by combining residual-based metrics with task-specific criteria to improve accuracy.

Additionally, or in an alternative, the system may maintain a bank of best candidate parameters. The bank stores the best candidates determined during different iterations, and the stored candidates are evaluated and updated based on model scoring criteria to ensure retention of the most promising solutions across iterations. The bank of best candidate parameters may be implemented as a priority queue, with each candidate associated with a model score and iteration depth. The system may then prioritize candidates based on model scores and their respective iteration depth to ensure exploration of the most promising solutions first. The bank enforces a maximum size, retaining only candidates with sufficiently distinct model parameters and high scores. The system iteratively re-evaluates candidates from the bank and updates the bank based on newly sampled parameters and scoring criteria during subsequent iterations. For each iteration, the annealing factors modify only the current parameter to form new candidates, such that the bank maintains a diverse set of candidates generated by modifying different parameters with randomly sampled annealing factors, ensuring comprehensive exploration of the solution space across iterations.

In some embodiments, the environment model is used to generate a map for autonomous navigation by fitting geometric structures, such as road boundaries, lane markings, and obstacles, enabling real-time path planning and obstacle avoidance in noisy or cluttered environments. In the same or other embodiments, the model may be used for Simultaneous Localization and Mapping (SLAM) to estimate the robot's pose and create an accurate map of the environment by handling outlier-contaminated feature matches. In such embodiments, the robust loss function accounts for noise from sensors, such as LIDAR or cameras, to enhance the accuracy of detecting and modeling dynamic elements, including pedestrians and moving vehicles, robotic elements, and the like.

In robotics applications, the annealing factors may be optimized to adaptively refine the robot's position and orientation by aligning point cloud data with previously mapped features, ensuring precise navigation in dynamic or unknown environments. For example, the model may be used to define the geometry of objects within a workspace for robotic manipulation, enabling automated systems to accurately identify and handle components despite variations in sensor data quality. The adaptive annealing framework optimizes parameters for aligning and manipulating objects with varying shapes and orientations, ensuring robust performance in manufacturing and assembly processes.

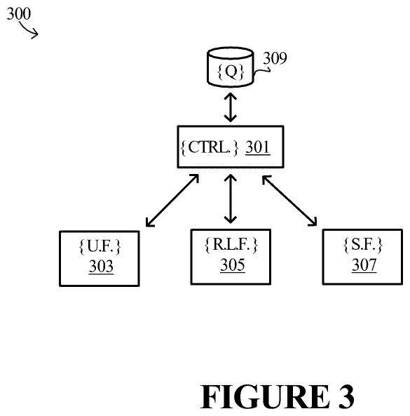

FIG. 3 illustrates system architecture 300 in an implementation of the adaptive annealing framework disclosed herein. At a high level, the components of system architecture 300 employ a best-hypothesis approach that explores multiple hypotheses at each iteration (k) of an optimization algorithm to find a best shape parameter for a robust loss function. The algorithm iteratively refines the model and parameters, ensuring that the best hypothesis is found by continuously evaluating and updating the hypotheses based on multiple annealing factors and model scores. Throughout the iterations, the algorithm compares new hypotheses with the best one found so far and retains the best overall hypothesis, even if it was discovered in an earlier iteration. This ensures that the final output is the best possible hypothesis the algorithm encountered during its entire run. Stopping criteria ensure that the loop eventually terminates once an optimal solution or a satisfactory stopping condition is reached. Essentially, the algorithm iteratively optimizes model parameters to adapt to the data and features observed during each particular iteration. The goal is to find the optimal model parameters that best fit the data at that specific moment, ensuring that the model remains accurate and robust to the real-world features it encounters.

More specifically, system architecture 300 is representative of a computing hardware, software, and/or firmware architecture suitable for implementing a computer vision system with adaptive annealing capabilities, such as computer vision system 101 in FIG. 1. System architecture 300 includes a control block 301, an update function 303, a robust loss function (RLF 305), a scoring function 307, and a queue 309, each of which may be implemented in hardware, software, firmware, or a combination thereof.

Control block 301 is representative of one or more components capable of process initialization, iteration management, stopping evaluation, queue management, and other such decision making. Control block 301 controls a main loop of an algorithm, while iterating through annealing and model computation steps, while checking if the algorithm should stop based on predefined criteria or maximum iterations. Control block 301 also performs queue management with respect to queue 309.

Update function 303 is representative of one or more components capable of updating a shape parameter per instructions provided by control block 301. Update function 303 returns updated instances of the shape parameter to control block 301. RLF 305 is representative of one or more components capable of interfacing with control block 301 to obtain the updated shape parameters and other data, with which it computes updated model parameters and residuals used by scoring function 307 to compute hypothesis scores. Accordingly, scoring function 307 is representative of one or more components capable of computing such scores.

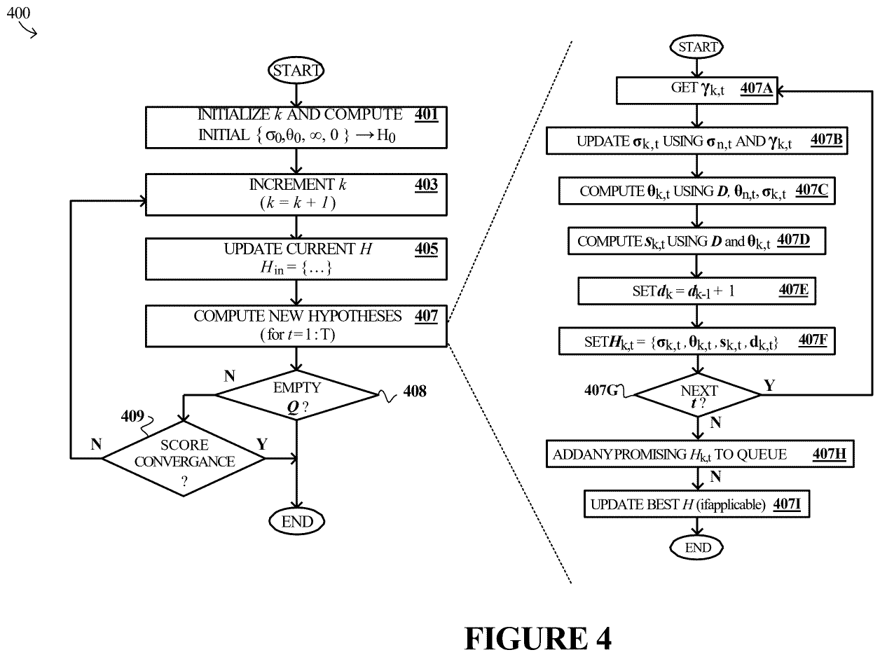

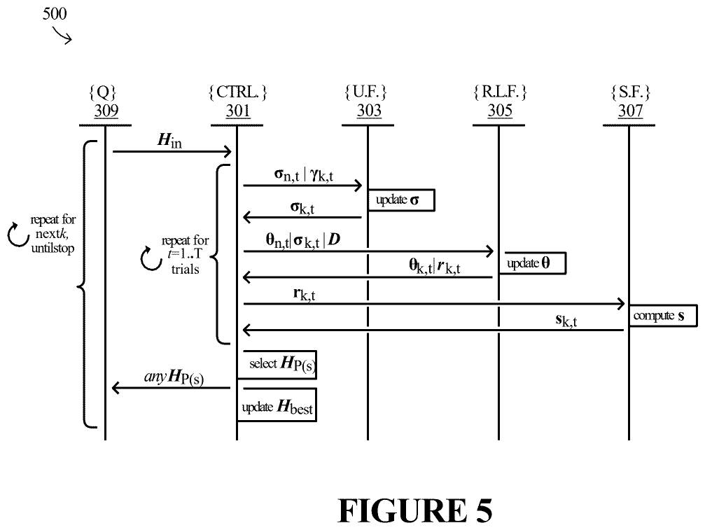

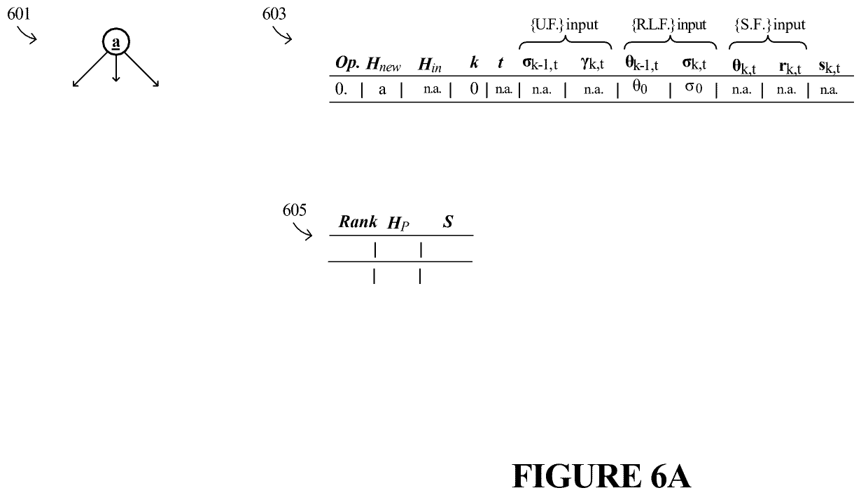

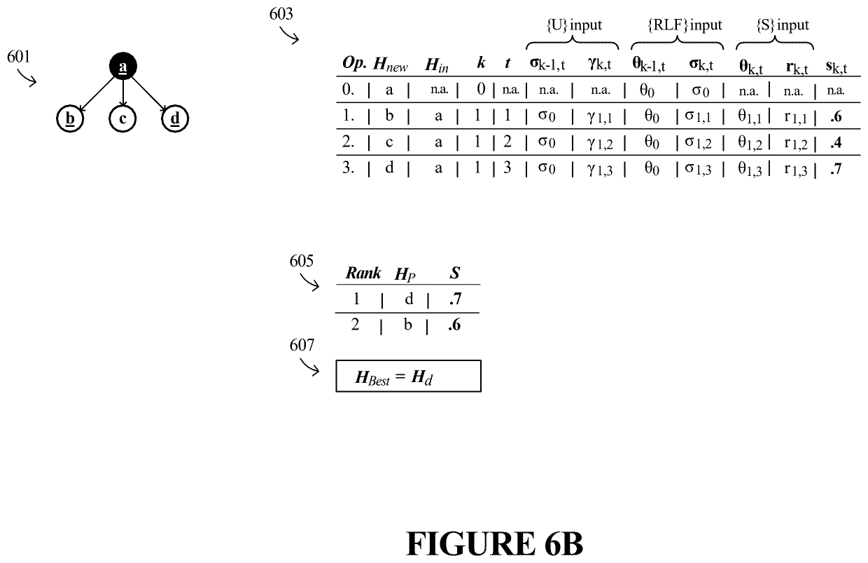

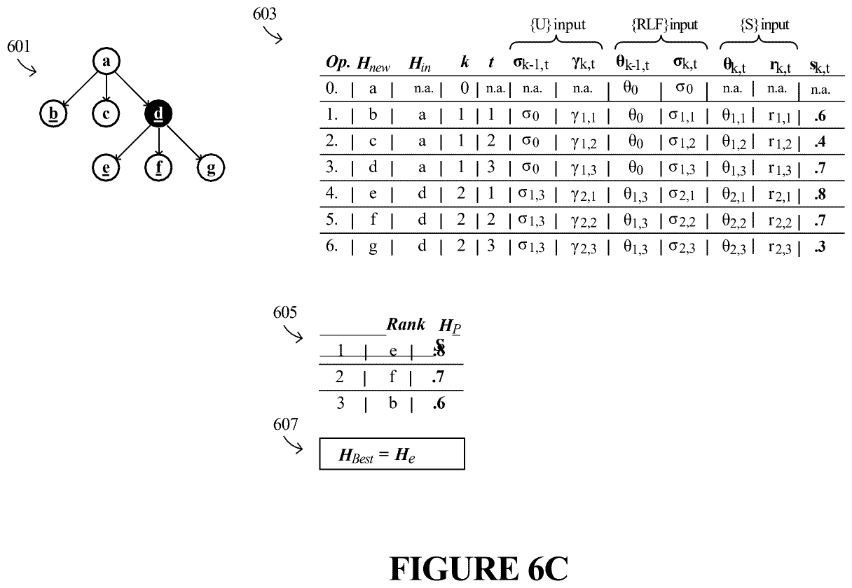

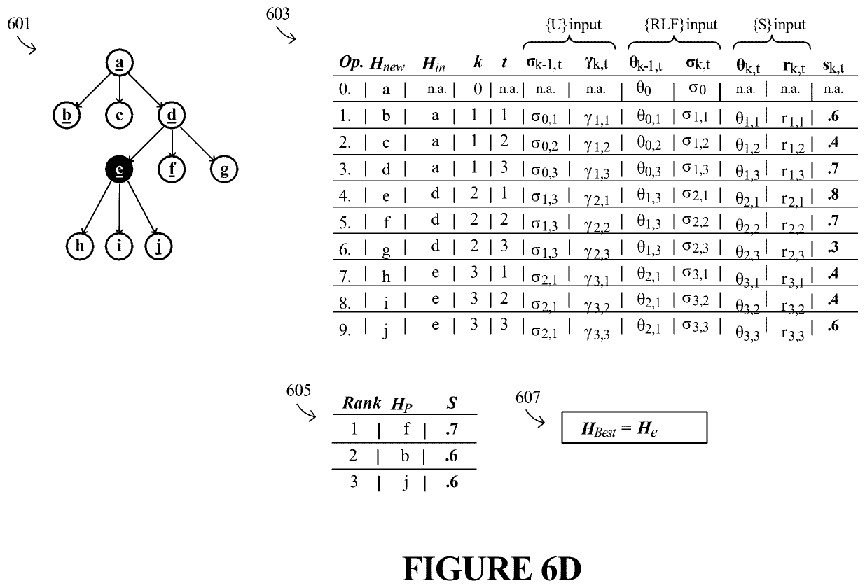

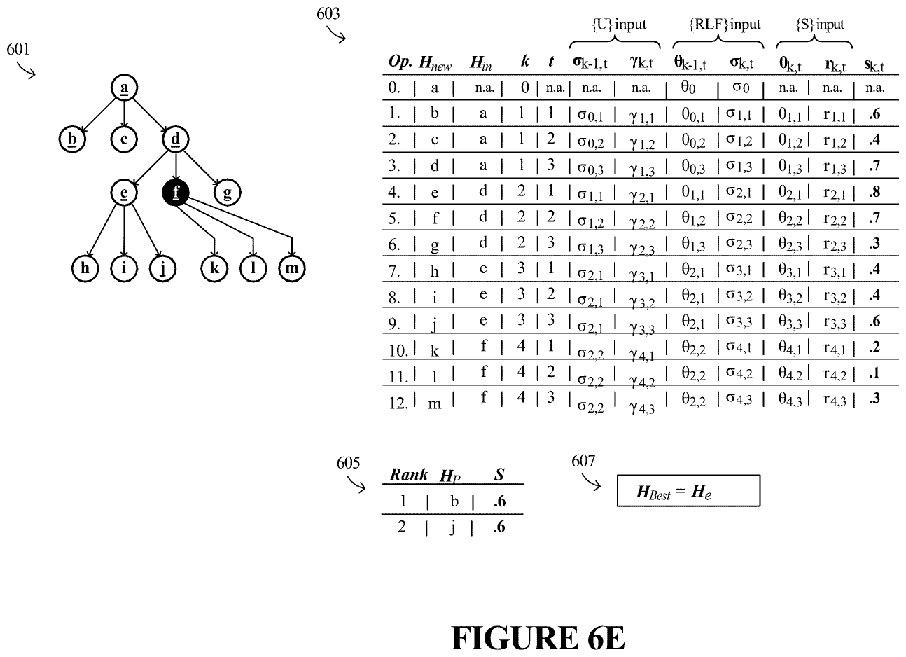

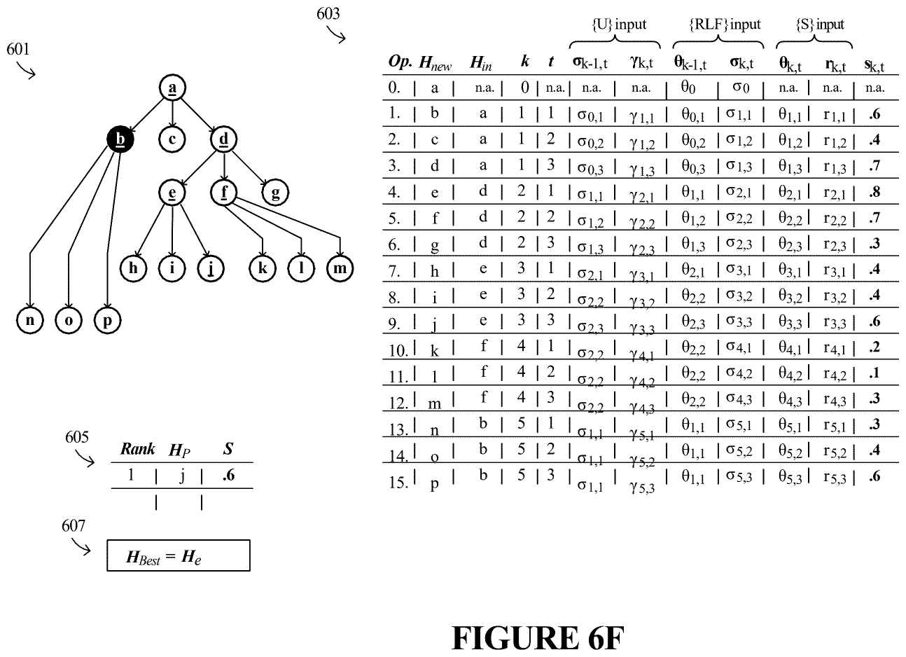

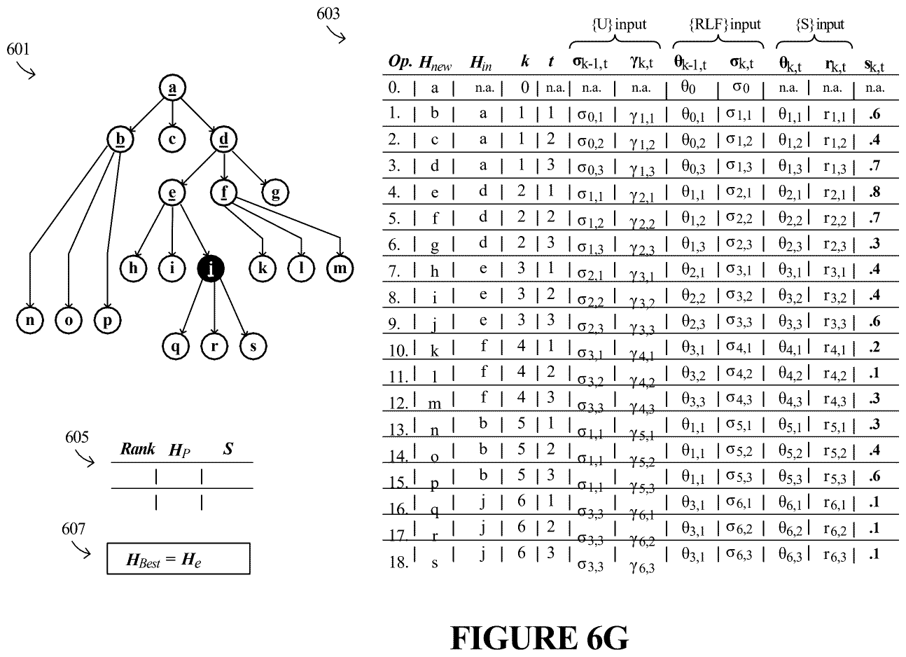

Parameter optimization process 400, illustrated in FIG. 4, is representative of an algorithm implemented by the components of system architecture 300 to achieve the adaptive annealing framework discussed above. The discussion of FIG. 4 below is followed by a related discussion of FIG. 5, which illustrates an application of parameter optimization process 400 in the context of the elements of FIG. 3. FIGS. 6A-6G illustrate a specific application of parameter optimization process with respect to an exemplary operational scenario.

Referring now to FIG. 4, parameter optimization process 400 may be implemented in program instructions in the context of software, and/or firmware elements of system architecture 300, or in specialized circuitry configured to execute its logic. The logic (whether embodied in program instructions or specialized circuitry), when executed by one or more processing devices of one or more suitable computing devices, directs the one or more computing devices to operate as follows, referring to the steps of FIG. 4, and to a system in the singular for purposes of clarity.

To begin, the system computes a least squares solution to produce initial model residuals, which may then be used to initialize a shape parameter and to compute initial model parameters, resulting in an initial hypothesis (Step 401). Note that the initial hypothesis may be represented by H_0→{σ_0, θ_0, s_0, and d_0}, where the current iteration k=0, σ (sigma) represents the shape parameter, θ (theta) represents model parameters, s represents a score for the hypothesis (infinite at k=0), and d represents a level of depth in a tree search (0 at k=0). Further at this step, the queue (Q) is set to empty.

Next, the algorithm enters a main loop that iterates until certain stopping conditions are met. The first step in the main loop is to increment k by k=k+1 (Step 403). In addition, the current parameters with which to develop new hypotheses are identified (Step 405). The current parameters are used to seed the generation of new parameters for each trial hypothesis tested during each iteration of the main loop. For the first iteration through the main loop, where k=1, the current parameters are drawn from the initial parameters determined in Step 403. For subsequent iterations through the main loop, the current parameters are drawn from a next hypothesis selected from the queue to be explored. For example, for k=1, the hypothesis inputs (H_in) to be used during each trial (t=1 . . . T) are σ_0 and θ_0. For later iterations, the hypothesis inputs (H_in) to be used during each trial (t=1 . . . T) are σ_n,t and θ_n,t where the combination of n and t identify the hypothesis being explored.

The trial stage involves computing new hypotheses to test based on the hypothesis inputs associated with the selected hypothesis (Step 407). This stage of computation involves an inner loop represented by Steps 407A-407I. The inner loop iterates T times, each time computing and evaluating a trial hypothesis as follows.

At Step 407A, the system obtains an annealing factor represented by γ_k,t. Next, the system updates an instance of the shape parameter (σ_k,t) based on σ_n,t and γ_k,t (Step 407B). Trial model parameters (θ_k,t) are then computed using input data (D), as well as the updated shape parameter (σ_k, t), and the model parameters associated with the previous hypothesis being explored (θ_n,t) (Step 407C).

Having computed new model parameters, the system computes a score for the new hypothesis (s_k,t) based on the trial model parameters and the input data (Step 407D). In one example, the score may be computed using the weighted or non-weighted residuals to compute a sum of the truncated squared residuals.

The new hypothesis is then defined by incrementing the depth level in the tree to indicate the depth of the new hypothesis (Step 407E) and then setting the values of the new hypothesis. As an example, at an iteration k and trial t, the parameters of new hypothesis H_k,t are defined as: {σ_k,t; θ_k,t; s_k,t; and d_k,t} . Should this hypothesis be selected later for exploration, the input parameters for the new hypotheses being explored would be drawn from these parameters.

At Step 407G, the system determines whether any trials remain. If so, the inner loop comprised of Steps 407A-407F repeats, until all trials have been completed. Upon completing the trials, the system evaluates the resulting trial hypotheses to determine whether any one or more are promising enough to add to the queue (Step 407H).

A trial hypothesis may qualify as a promising hypothesis—and thus one to add to the queue for later exploration—based on a variety of heuristics. For instance, any hypothesis with a shape parameter value below a minimum threshold value is excluded from the queue. Secondly, the best scoring hypothesis of the set of trial hypotheses is added to the queue, unless its shape parameter value falls below the minimum threshold. In addition, only a maximum number of new hypotheses can be added to the queue for each iteration of k. If two or more of the trial hypotheses have similar scores, only those with sufficiently different model parameters relative to others of the trial hypothesis are added to the queue. If a maximum size of the queue is exceeded after having added any promising hypotheses to the queue, hypotheses with lower scores are discarded until the maximum queue size is discarded.

Lastly, the system updates an overall best hypothesis based on the best one of the trial hypotheses under consideration (Step 407I). The overall best hypothesis, which is populated during previous iterations of k, is only replaced with a new hypothesis if the new hypothesis has a score that exceeds that of the current overall best hypothesis.

Upon completion of Steps 407A-407I, the system returns to the main loop at Step 408. At this step, the system determines whether the queue is empty. If so, then the algorithm ends, and the model parameters are set to those produced by the overall best hypothesis. If the queue is not empty, the system determines whether scores in the queue have sufficiently converged (Step 409). If so, then the algorithm also ends. If not, then the system returns to Step 403 and continues to iterate through the main loop.

FIG. 5 illustrates an operational scenario 500 that describes an application of parameter optimization process 400 with respect to the elements of system architecture 300 for a given iteration k of the process. In operation, control block selects a hypothesis from queue 309 to explore with respect to T annealing factors. The parameters of the selected hypothesis include a shape parameter (σ_n,t) and model parameters (θ_n,t).

For T iterations, control block 301 passes the shape parameter (σ_n,t) and the next annealing factor (γ_n,t) to update function 303. Update function 303 modifies the shape parameter based on the annealing factor, resulting in an updated shape parameter (σ_k,t), and passes the updated shape parameter to control block 301. Control block 301 then invokes RLF 305 to compute updated model parameters.

Specifically, control block 301 passes the updated shape parameter (σ_k,t), the previous model parameters (θ_n,t), and input data (D) to RLF 305. RLF internally computes new model parameters and residuals (r_k,t), which it returns to control block 301. Control block 301 passes the residuals to scoring function 307, which it uses to compute a score for the new hypothesis.

After T annealing trials, control block 301 evaluates the scores for the respective trials to determine whether to add any promising hypotheses to queue 309. In addition, control block determines whether to update the overall best hypotheses with one of the hypotheses in the set of trial hypotheses.

FIGS. 6A-6G illustrate another operational scenario 600 to further demonstrate an application of parameter optimization process 400. Search tree 601 represents the exploration of various hypotheses over the course of k iterations. Table 603 illustrates the iterations of the main loop over the course of the k iterations. Queue 605 represents a queue that holds promising hypotheses after each iteration.

Referring to FIG. 6A, the process beings at k=0 with an initial hypothesis “a,” denoted here as H_a. The shape parameters and model parameters are initialized, which are represented by σ_0 and θ_0. The queue 605 is empty at k=1.

At the next iteration, k=1, illustrated in FIG. 6B, a set of trial hypotheses are computed for t=1 to T, where T=3 in operations 1-3, which may be computed in parallel with respect to each other. Thus, three (3) trial hypotheses are computed using the shape and model parameters from k=0 (σ_0 and θ_0), as well as three randomly, semi-randomly, and/or pseudo-randomly selected annealing factors (γ_1,1; γ_1,2; and γ_1,3). The shape parameter is modified for each trial based on the corresponding annealing factor, resulting in three updated instances of the shape parameter: σ_1,1; σ_1,2; and σ_1,3.

For each trial hypothesis, the corresponding updated shape parameter and the previous model parameters (θ_0) are supplied as input to a robust loss function (RLF). The RFL computes updated model parameters for each trial, represented by: θ_1,1; θ_1,2; and θ_1,3. Each set of updated model parameters and residuals (r_1,1; r_1,2; and r_1,3) corresponding to each trial hypothesis (H_b, H_c, and H_d) are provided to a scoring function to score each respective hypothesis. The resulting scores are represented by: s_1,1=.6; s_1,2=.4; and s_1,3=.07. Thus, the hypothesis H_d has the highest score, followed by H_b, and then H_c.

The hypothesis with the highest score (H_d) is added to the queue 605, as is H_b. It is assumed for exemplary purposes that the minimum score threshold is 0.5, excluding H_c from the queue. As H_d has the highest score in the queue, it is selected next for exploration. In addition, H_d is designated as the best overall score 607 after k=1.

FIG. 6C illustrates the exploration of H_d in operations 4-6 for k=2, which may be computed in parallel with each other. Three trial hypotheses are again computed, but using the shape and model parameters associated with H_d, which include σ_1,3 and θ_1,3), as well as three randomly, semi-randomly, and/or pseudo-randomly selected annealing factors (γ_2,1; γ_2,2; and γ_2,3). The shape parameter is modified for each trial based on the corresponding annealing factor, resulting in updated instances of the shape parameter: σ_2,1; σ_2,2; and σ_2,3.

For each trial hypothesis, the corresponding updated shape parameter and the previous model parameters are supplied as input to a robust loss function. The RFL computes updated model parameters for each trial, represented by: θ_2,1; θ_2,2; and θ_2,3. Each set of updated model parameters and residuals (r_2,1; r_2,2; and r_2,3) corresponding to each trial hypothesis (H_e, H_f, and H_g) are provided to a scoring function to score each respective hypothesis. The resulting scores are represented by: s_2,1=0.8; s_2,2=0.7; and s_2,3=0.3. Thus, the hypothesis H_e has the highest score, followed by H_f, and then H_g. The hypothesis with the highest score (H_e) is added to the queue 605, as is H_f. However, H_g is excluded since its score fails to meet or exceed the threshold score. Moreover, note that H_d has been replaced as the best overall score 607 by H_e.

In FIG. 6D, the hypothesis exploration continues with respect to H_e (operations 7-9 for k=3, since it is the highest scoring hypothesis in the queue. Three trial hypotheses are again computed and evaluated (possibly in parallel if desired), but using the shape and model parameters associated with H_e, which include σ_2,1 and θ_2,1), as well as three randomly, semi-randomly, and/or pseudo-randomly selected annealing factors (γ_3,1; γ_3,2; and γ_3,3). The shape parameter is modified for each trial based on the corresponding annealing factor, resulting in three updated instances of the shape parameter: σ_3,1; σ_3,2; and σ_3,3.

For each trial hypothesis, the corresponding updated shape parameter and the previous model parameters are supplied as input to the robust loss function. The RFL computes updated model parameters for each trial, represented by: θ_3,1; θ_3,2; and θ_3,3. Each set of updated model parameters and residuals (r_3,1; r_3,2; and r_3,3) corresponding to each trial hypothesis (H_h, H_i, and H_j) are provided to the scoring function to score each respective hypothesis. The resulting scores are represented by: s_3,1=0.4; s_3,2=0.4; and s_3,3=0.6. Thus, the hypothesis H_j has the highest score, followed by H_h and H_i. The hypothesis with the highest score (H_j) is added to the queue 605, but H_h and H_i are excluded as being too low to qualify as promising hypotheses. Note that H_e remains as the best overall hypothesis 607.

The exploration proceeds in FIG. 6E to H_f, since it is the next highest scoring hypothesis in the queue. Note that H_b is bypassed at the moment, even though it resides at a high level of depth in the search tree. The exploration of H_f involves operations 10-12 for k=4.

Three trial hypotheses are again computed and evaluated (in parallel if so desired), but using the shape and model parameters associated with H_f, which include σ_2,2 and θ_2,2), as well as three randomly, semi-randomly, and/or pseudo-randomly selected annealing factors (γ_4,1; γ_4,2; and γ_4,3). The shape parameter is modified for each trial based on the corresponding annealing factor, resulting in updated instances of the shape parameter: σ_4,1; σ_4,2; and σ_4,3.

For each trial hypothesis, the corresponding updated shape parameter and the previous model parameters are supplied as input to the robust loss function. The RFL computes updated model parameters for each trial, represented by: θ_4,1; θ_4,2; and θ_4,3. Each set of updated model parameters and residuals (r_4,1; r_4,2; and r_4,3) corresponding to each trial hypothesis (H_k, H_l, and H_m) are provided to the scoring function to score each respective hypothesis. The resulting scores are represented by: s_4,1=0.2; s_4,2=0.1; and s_4,3=0.3. Thus, none of the resulting trial hypotheses are added to the queue and H_e remains as the best overall hypothesis 607.

In FIG. 6F, the exploration returns to H_b, since it is highest scoring hypothesis remaining in the queue. The exploration of H_b involves operations 13-15 for k=5.

Three trial hypotheses are again computed and evaluated (in parallel if so desired), but using the shape and model parameters associated with H_b, which include σ_1,1 and θ_1,1 as well as three randomly, semi-randomly, and/or pseudo-randomly selected annealing factors (γ_5,1; γ_5,2; and γ_5,3). The shape parameter is modified for each trial based on the corresponding annealing factor, resulting in updated instances of the shape parameter: σ_5,1; σ_5,2; and σ_5,3.

For each trial hypothesis, the corresponding updated shape parameter and the previous model parameters are supplied as input to the robust loss function. The RFL computes updated model parameters for each trial, represented by: θ_5,1; θ_5,2; and θ_5,3. Each set of updated model parameters and residuals (r_5,1; r_5,2; and r_5,3) corresponding to each trial hypothesis (H_n, H_o, and H_p) are provided to the scoring function to score each respective hypothesis. The resulting scores are represented by: s_5,1=0.3; s_4,2=0.4; and s_4,3=0.6. Only H_p has a high enough score to qualify as promising. However, its score is the same as H_j, which is already in the queue. It is assumed for exemplary purposes that the parameters of H_p are not sufficiently different from those of H_j, and so it is excluded from the queue, leaving H_j as the only remaining hypothesis in the queue. H_j is therefore explored next, while H_e remains as the best overall hypothesis 607.

FIG. 6G illustrates the exploration of H_j. The exploration of H_J involves operations 16-18 for k=6. Three trial hypotheses are again computed and evaluated (in parallel if so desired), but using the shape and model parameters associated with H_j, which include σ_3,3 and θ_3,3 as well as three randomly, semi-randomly, and/or pseudo-randomly selected annealing factors (γ_6,1; γ_6,2; and γ_6,3). The shape parameter is modified for each trial based on the corresponding annealing factor, resulting in updated instances of the shape parameter: σ_6,1; σ_6,2; and σ_6,3.

For each trial hypothesis, the corresponding updated shape parameter and the previous model parameters are supplied as input to the robust loss function. The RFL computes updated model parameters for each trial, represented by: θ_6,1; θ_6,2; and θ_6,3. Each set of updated model parameters and residuals (r_6,1; r_6,2; and r_6,3) corresponding to each trial hypothesis (H_q, H_r, and H_s) are provided to the scoring function to score each respective hypothesis. The resulting scores are represented by: s_6,1=0.1; s_6,2=0.1; and s_6,3=0.1. None of the resulting hypotheses have high enough scores to qualify as promising. As such, none are added to the queue. In addition, the queue is now empty, and the main loop is therefore finished. Processing is complete and H_e, being the best overall hypothesis, is used with respect to continued processing of the model. For instance, a task may be performed using the model when the termination condition is met.

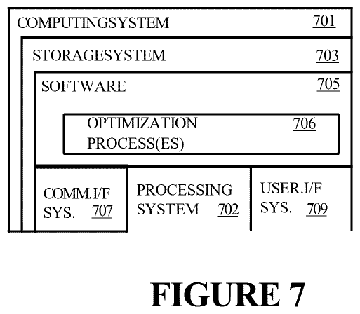

FIG. 7 illustrates computing device 701 that is representative of any system or collection of systems in which the various processes, programs, services, and scenarios disclosed herein may be implemented. Examples of computing device 701 include, but are not limited to, general-purpose computing systems, such as standard server computers, desktop and laptop computers, tablet computers, gaming consoles, mobile phones, and wearable devices (including headphones, eyeglasses, and ear buds). Other examples of computing device 701 include: high-performance computing (HPC) clusters; graphics processing units (GPUs) or other such specialized hardware designed for parallel processing; embedded systems, including microcontrollers and System-on-Chip (SoC) devices; cloud computing platforms that provide scalable resources on-demand; and field-programmable gate arrays (FPGAs).

Computing device 701 may be implemented as a single apparatus, system, or device or may be implemented in a distributed manner as multiple apparatuses, systems, or devices. Computing device 701 includes, but is not limited to, processing system 702, storage system 703, software 705, communication interface system 707, and user interface system 709. Processing system 702 is operatively coupled with storage system 703, communication interface system 707, and user interface system 709.

Processing system 702 loads and executes software 705 from storage system 703. Software 705 includes and implements parameter optimization process(es) 706, which is representative of the parameter optimization and/or estimation methods and processes described above. When executed by processing system 702, software 705 directs processing system 702 to operate as described herein for at least the various processes, operational scenarios, and sequences discussed in the foregoing implementations. Computing device 701 may optionally include additional devices, features, or functionality not discussed for purposes of brevity.

Referring still to FIG. 7, processing system 702 may comprise a micro-processor and other circuitry that retrieves and executes software 705 from storage system 703. Processing system 702 may be implemented within a single processing device but may also be distributed across multiple processing devices or sub-systems that cooperate in executing program instructions. Examples of processing system 702 include general purpose central processing units, graphical processing units, digital signal processors, application specific processors, and logic devices, as well as any other type of processing device, combinations, or variations thereof.

Storage system 703 may comprise any computer readable storage media readable by processing system 702 and capable of storing software 705. Storage system 703 may include volatile and nonvolatile, removable and non-removable media implemented in any method or technology for storage of information, such as computer readable instructions, data structures, program modules, or other data. Examples of storage media include random access memory, read only memory, magnetic disks, optical disks, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 703 may also include computer readable communication media over which at least some of software 705 may be communicated internally or externally. Storage system 703 may be implemented as a single storage device but may also be implemented across multiple storage devices or sub-systems co-located or distributed relative to each other. Storage system 703 may comprise additional elements, such as a controller, capable of communicating with processing system 702 or possibly other systems.

Software 705 (including parameter optimization process(es) 706) may be implemented in program instructions and among other functions may, when executed by processing system 702, direct processing system 702 to operate as described with respect to the various operational scenarios, sequences, and processes illustrated herein. For example, software 705 may include program instructions for implementing the parameter optimization and/or estimation processes described herein.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 705 may include additional processes, programs, or components, such as operating system software, virtualization software, or other application software. Software 705 may also comprise firmware or some other form of machine-readable processing instructions executable by processing system 702.

In general, software 705 may, when loaded into processing system 702 and executed, transform a suitable apparatus, system, or device (of which computing device 701 is representative) overall from a general-purpose computing system into a special-purpose computing system customized to perform parameter optimization and/or estimation in an optimized manner. Indeed, encoding software 705 on storage system 703 may transform the physical structure of storage system 703. The specific transformation of the physical structure may depend on various factors in different implementations of this description. Examples of such factors may include, but are not limited to, the technology used to implement the storage media of storage system 703 and whether the computer-storage media are characterized as primary or secondary storage, as well as other factors.

For example, if the computer readable storage media are implemented as semiconductor-based memory, software 705 may transform the physical state of the semiconductor memory when the program instructions are encoded therein, such as by transforming the state of transistors, capacitors, or other discrete circuit elements constituting semiconductor memory. A similar transformation may occur with respect to magnetic or optical media. Other transformations of physical media are possible without departing from the scope of the present description, with the foregoing examples provided only to facilitate the present discussion.

Communication interface system 707 may include communication connections and devices that allow for communication with other computing systems (not shown) over communication networks (not shown). Examples of connections and devices that together allow for inter-system communication may include network interface cards, antennas, power amplifiers, RF circuitry, transceivers, and other communication circuitry. The connections and devices may communicate over communication media to exchange communications with other computing systems or networks of systems, such as metal, glass, air, or any other suitable communication media. The aforementioned media, connections, and devices are well known and need not be discussed at length here.

Communication between computing device 701 and other computing systems (not shown), may occur over a communication network or networks and in accordance with various communication protocols, combinations of protocols, or variations thereof. Examples include intranets, internets, the Internet, local area networks, wide area networks, wireless networks, wired networks, virtual networks, software defined networks, data center buses and backplanes, or any other type of network, combination of network, or variation thereof. The aforementioned communication networks and protocols are well known and need not be discussed at length here.

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosure may take the form of a computer program product embodied in one or more computer readable medium(s) having computer readable program code embodied thereon.

Indeed, the included descriptions and figures depict specific embodiments to teach those skilled in the art how to make and use the best mode. For the purpose of teaching inventive principles, some conventional aspects have been simplified or omitted. Those skilled in the art will appreciate variations from these embodiments that fall within the scope of the disclosure. Those skilled in the art will also appreciate that the features described above may be combined in various ways to form multiple embodiments. As a result, the disclosure is not limited to the specific embodiments described above, but only by the claims and their equivalents.

What is claimed is:

1. A computer-vision method for performing a task in an environment represented by noisy measurements, wherein the method uses a processor coupled with stored instructions implementing the method, wherein the instructions, when executed by the processor carry out steps of the method, comprising:
collecting data representing the environment, wherein the data is contaminated with outliers caused at least in part by the noisy measurements of the environment;
collecting a structure of a model of the environment suitable for performing the task;
determining values of the structure of the model fitting the collected outlier-contaminated environmental data by solving an M-estimation optimization problem that iteratively minimizes a robust loss function of a solution for fitting the model into the data using a parameter defining a convex space of the solution until a termination condition is met, wherein, for at least one current iteration, a current parameter is selected from multiple semi-random parameters representing a previous parameter determined during a previous iteration and modified with annealing factors randomly sampled within a predetermined range; and
performing the task using the model of the environment when the termination condition is met.

2. The method of claim 1, wherein the current iteration comprises:
collecting a previous solution and the previous parameter of a convex space of the previous solution determined during the previous iteration;
sampling the annealing factors on the predetermined range;
modifying the previous parameter with the sampled values of the annealing factors to produce the multiple semi-random parameters; and
comparing each of the multiple semi-random parameters with the previous solution to select a value of the current parameter.

3. The method of claim 1, wherein the robust loss function comprises a Geman-McClure function or another function to reduce the influence of extreme outliers by dynamically adjusting the weight of residuals based on a shape parameter.

4. The method of claim 3, wherein the shape parameter is iteratively updated using a sampling strategy within an adaptive annealing framework.

5. The method of claim 1, wherein the annealing factors are selected from a predefined range using a probabilistic sampling method to optimize the convexity of the solution space.

6. The method of claim 1, wherein the model scoring function evaluates the robustness of candidate parameters by combining residual-based metrics with task-specific criteria to improve accuracy.

7. The method of claim 1, wherein the termination condition is determined based on convergence of model parameters, scoring consistency, or depletion of promising hypotheses in a priority queue.

8. The method of claim 1, wherein the computational process utilizes parallel execution for evaluating multiple hypotheses during each iteration to enhance computational efficiency.

9. The method of claim 1, wherein the model structure is defined based on task-specific requirements, including, but not limited to, geometric transformations, feature alignments, or spatial constraints.

10. The method of claim 1, further comprising:
maintaining a bank of best candidate parameters, wherein the bank stores the best candidates determined during different iterations, and the stored candidates are evaluated and updated based on model scoring criteria.

11. The method of claim 10, wherein the bank of best candidate parameters is implemented as a priority queue, wherein:
each candidate is associated with a model score and iteration depth,
candidates are prioritized based on model scores and their respective iteration depth,
the bank enforces a maximum size, retaining only candidates with sufficiently distinct model parameters and high scores, and
candidates from the bank are iteratively re-evaluated and updated based on newly sampled parameters and scoring criteria during subsequent iterations.

12. The method of claim 10, wherein, for each iteration, the annealing factors modify only the current parameter to form new candidates, such that the bank maintains a diverse set of candidates generated by modifying different parameters with randomly sampled annealing factors.

13. The method of claim 1, wherein different tasks are received, and for each task, a structure of the model specific to the task is derived, but the same framework is used to determine the parameters for fitting the derived model structures.

14. A memory having program instructions stored thereon for performing a task in an environment represented by noisy measurements, wherein the instructions, when executed by one or more processors of a computing device, direct the computing device to at least:
collect data representing the environment, wherein the data is contaminated with outliers caused at least in part by the noisy measurements of the environment;
collect a structure of a model of the environment suitable for performing the task;
determine values of the structure of the model fitting the collected outlier-contaminated environmental data by solving an M-estimation optimization problem that iteratively minimizes a robust loss function of a solution for fitting the model into the data using a parameter defining a convex space of the solution until a termination condition is met, wherein, for at least one current iteration, a current parameter is selected from multiple semi-random parameters representing a previous parameter determined during a previous iteration and modified with annealing factors randomly sampled within a predetermined range; and
perform the task using the model when the termination condition is met.

15. The memory of claim 14, wherein during the current iteration, the instructions direct the computing device to:
collect a previous solution and the previous parameter of a convex space of the previous solution determined during the previous iteration;
sample the annealing factors on the predetermined range;
modify the previous parameter with the sampled values of the annealing factors to produce the multiple semi-random parameters; and
compare each of the multiple semi-random parameters with the previous solution to select a value of the current parameter.

16. The memory of claim 15, wherein:
the robust loss function comprises a Geman-McClure function or another function to reduce the influence of extreme outliers by dynamically adjusting the weight of residuals based on a shape parameter;
the shape parameter is iteratively updated using a sampling strategy within an adaptive annealing framework; and
the annealing factors are selected from a predefined range using a probabilistic sampling method to optimize the convexity of the solution space.

17. The memory of claim 14, wherein the termination condition is determined based on convergence of model parameters, scoring consistency, and depletion of promising hypotheses in a priority queue.

18. The memory of claim 14, wherein the instructions further direct the computing device to maintain a bank of best candidate parameters, wherein the bank stores the best candidates determined during different iterations, and the stored candidates are evaluated and updated based on model scoring criteria.

19. The memory of claim 18 wherein, for each iteration, the annealing factors modify only the current parameter to form new candidates, such that the bank maintains a diverse set of candidates generated by modifying different parameters with different annealing factors.

20. A computing apparatus comprising:
one or more computer readable storage media;
one or more processors operatively coupled with the one or more computer readable storage media; and
program instructions stored on the one or more computer readable storage media that, when executed by the one or more processors, direct the computing apparatus to at least:
perform an optimization process to optimize a set of model parameters associated with a model of an observed system, wherein to perform the optimization process, the program instructions direct the computing apparatus to, for an iteration of the optimization process:
select, from a set of promising hypotheses, a hypothesis computed during a previous iteration of the optimization process, wherein the possible hypothesis comprises a previous shape parameter and previous model parameters; and
generate a set of new hypotheses corresponding to a set of trial annealing factors including by, for each new hypothesis of the set of new hypotheses:
compute a new shape parameter based on a corresponding one of the trial annealing factors and the previous shape parameter;
compute new model parameters based on the new shape parameter and previous residuals associated with the previous model parameters;
compute new residuals based on the new instance of the model parameters;
compute a score for the new hypothesis based on the new residuals; and
determine whether to add the new hypothesis to the set of promising hypotheses based on the score.
